(19) United States
(12) Patent Application Publication
(10) Pub. No.: US 2024/0282666 A1
(43) Pub. Date: Aug. 22, 2024

(54) SEMICONDUCTOR DEVICE AND POWER CONVERTER

(71) Applicant: FUJI ELECTRIC CO., LTD., Kanagawa (JP)

(72) Inventors: Yuta NAKAJIMA, Tokyo (JP); Keisuke OGURA, Tokyo (JP)

(21) Appl. No.: 18/647,287

(22) Filed: Apr. 26, 2024

Related U.S. Application Data
(63) Continuation of application No. PCT/JP2023/016200, filed on Apr. 25, 2023.

(30) Foreign Application Priority Data
May 30, 2022 (JP) 2022-087638

(51) Int. Cl. H01L 23/42; H01L 23/373; H01L 23/40

(52) U.S. Cl. CPC H01L 23/42; H01L 23/3736; H01L 23/4006

(57) ABSTRACT

A semiconductor device comprising: a semiconductor package; a cooler for cooling the semiconductor package; a seal member provided between the semiconductor package and the cooler and having an opening penetrating therethrough between the semiconductor package and the cooler; and a thermally conductive member formed of a metal filling the opening, the metal having a fluidity.

### CROSS-REFERENCE TO RELATED APPLICATIONS

The present application is a continuation application of International Application No. PCT/JP2023/016200, filed on Apr. 25, 2023 and designating the U.S., which is based upon and claims priority to Japanese Patent Application No. 2022-087638, filed on May 30, 2022. The entire contents of these applications are incorporated herein by reference.

### BACKGROUND OF THE INVENTION

### 1. Field of the Invention

The present disclosure relates to a semiconductor device and power converter.

### 2. Background of the invention

Patent Literature 1 discloses an electronic apparatus having a semiconductor chip, a sink arranged above the semiconductor chip, and a thermally conductive material between the sink and the semiconductor chip. Patent Literature 1 also discloses that the electronic apparatus has a seal member surrounding the thermally conductive material. Patent Literature 1 further discloses that the thermally conductive material has a conductivity, and has a fluidity at least during operation of the semiconductor chip.

Patent Literature 2 discloses a cooling device for cooling a semiconductor chip which generates heat. Patent Literature 2 also discloses that the semiconductor chip has a holding frame bonded thereto, and that a heat receiving member of the cooling device is detachably bonded to the holding frame via a seal member. Patent Literature 2 further discloses that a sealed space is formed by a heat transfer surface of the semiconductor chip, the holding frame, and the heat receiving member, a liquid metal is accommodated in the sealed space, and heat is transferred to the heat receiving member by the liquid metal.

When a semiconductor package having a semiconductor chip is cooled, there is a case where a fluid metal is provided as a thermally conductive material between the semiconductor package and a cooler for cooling the semiconductor package, and a thermal connection is made. When a metal having a fluidity is used to make the thermal connection between the semiconductor package and the cooler, the metal having a fluidity flows out from the semiconductor package and the cooler, and the thermal connection may be damaged. If the thermal connection between the semiconductor package and the cooler is damaged, the semiconductor chip in the semiconductor package may become hot, and a malfunction may occur.

### PRIOR ART LITERATURE

### Patent Literature

[Patent Literature 1] International Publication No. 2020/162417

[Patent Literature 2] Japanese Patent Publication No. 2010-212539

### SUMMARY OF THE INVENTION

According to one aspect of the present disclosure, a semiconductor device is provided, comprising: a semiconductor package; a cooler for cooling the semiconductor package; a seal member provided between the semiconductor package and the cooler, the seal member having an opening penetrating therethrough between the semiconductor package and the cooler; and a thermally conductive member formed of a metal filling the opening, the metal having a fluidity.

### BRIEF DESCRIPTION OF THE DRAWINGS

FIG. 1 is a perspective view of a semiconductor device according to a first embodiment.

FIG. 2 is an exploded perspective view of the semiconductor device according to the first embodiment.

FIG. 3 is a cross-sectional view of the semiconductor device according to the first embodiment.

FIG. 4 is a top view of a semiconductor package provided in the semiconductor device according to the first embodiment.

FIG. 5 is a bottom view of the semiconductor package provided in the semiconductor device according to the first embodiment.

FIG. 6 is a top view for showing an internal configuration of the semiconductor package provided in the semiconductor device according to the first embodiment.

FIG. 7 is a bottom view for showing an internal configuration of the semiconductor package provided in the semiconductor device according to the first embodiment.

FIG. 8 is a view for explaining an assembly of the semiconductor device according to the first embodiment.

FIG. 9 is a view for explaining an assembly of a semiconductor device according to a second embodiment.

FIG. 10 is a view for explaining an assembly of a semiconductor device according to a third embodiment.

FIG. 11 is an exploded perspective view of a semiconductor device according to a fourth embodiment.

FIG. 12 is an exploded perspective view of a semiconductor device according to a fifth embodiment.

FIG. 13 is an exploded perspective view of a semiconductor device according to a sixth embodiment.

FIG. 14 is an exploded perspective view of a semiconductor device according to a seventh embodiment.

FIG. 15 is a perspective view of a modified example of a semiconductor package provided in the semiconductor device according to the seventh embodiment.

### DESCRIPTION OF THE PREFERRED EMBODIMENTS

Hereinafter, each embodiment of the present invention will be described with reference to the accompanying drawings. It should be noted that, regarding the description of the specification and drawings related to each embodiment, redundant explanation may be omitted by assigning the same or corresponding reference numerals to components having substantially the same or corresponding functional configurations. In addition, for ease of understanding, the scale of each part in the drawings may differ from the actual scale.

A deviation in directions, such as “parallel”, “right-angled”, “orthogonal”, “horizontal”, “vertical”, “up and down”, and “left and right”, are allowed without impairing the effect of the embodiments. The shape of a corner is not limited to a right angle and may be rounded in an arc shape. The terms of “parallel”, “right-angled”, “orthogonal”, “horizontal”, and “vertical” may include “substantially parallel”, “substantially right-angled”, “substantially orthogonal”, “substantially horizontal”, and “substantially vertical”, respectively.

For example, the “substantially parallel” means that even if two lines or two faces are not perfectly parallel to each other, they can be treated as parallel to each other to the extent allowed in manufacturing. Regarding each of the remaining “substantially perpendicular”, “substantially orthogonal”, “substantially horizontal”, and “substantially vertical”, in similarity to the “substantially parallel”, it is also intended that the positional relationship between the two lines or two faces fall into the respective the positional category, long as relationship thereof is within the extent allowed in manufacturing.

According to the semiconductor device and power converter of the present disclosure, the semiconductor package can be stably cooled.

### First Embodiment

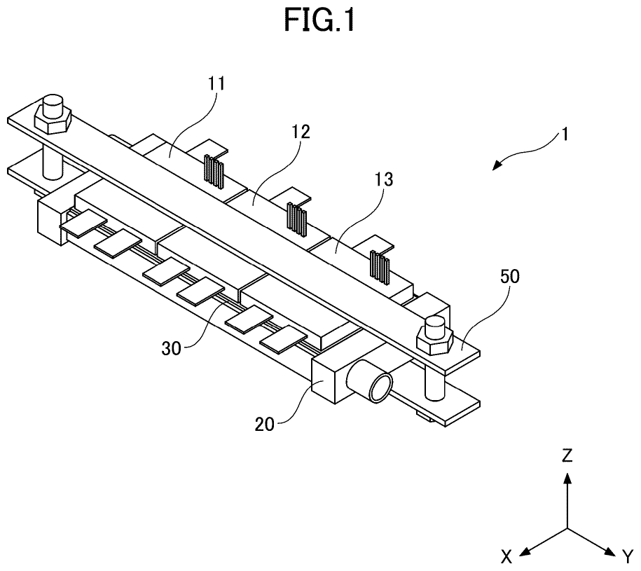

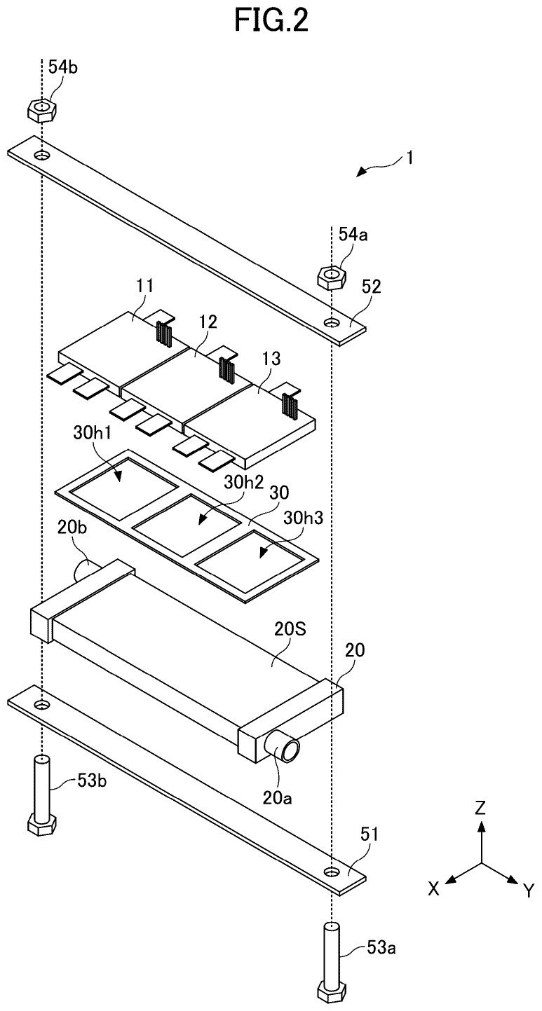

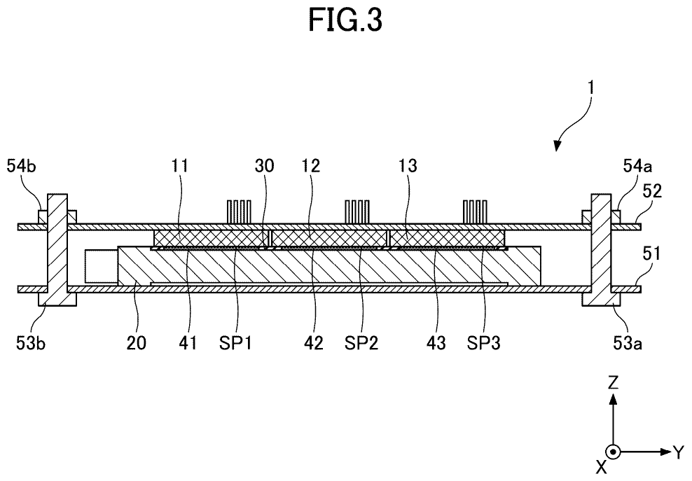

A semiconductor device 1 is a power converter for converting DC power into AC power. FIG. 1 is a perspective view of the semiconductor device 1 according to the first embodiment. FIG. 2 is an exploded perspective view of the semiconductor device 1 according to the first embodiment. FIG. 3 is a cross-sectional view of the semiconductor device 1 according to the first embodiment. Note that in FIG. 2, a thermally conductive member 41, a thermally conductive member 42, and thermally conductive member 43 are not shown. In FIG. 3, the internal configurations of a semiconductor package 11, a semiconductor package 12, a semiconductor package 13, and a cooler 20 are not shown.

In the drawings, a virtual three-dimensional coordinate system (XYZ Cartesian Coordinate System) consisting of a X axis, Y axis, and Z axis (XYZ axis) orthogonal to each other may be set for convenience of explanation. For example, for the coordinate axis perpendicular to the paper surface of the drawings, when a black circle is shown in the circle of the coordinate axis, it indicates that the front side relative to the paper surface is the positive area of the coordinate axis. When a cross is shown in the circle of the coordinate axis, it indicates that the front side relative to the paper surface is the negative area of the coordinate axis.

However, the coordinate system is provided for illustrative purposes, and is not intended to limit the posture of the semiconductor device or the like according to this embodiment.

Note that in the present disclosure, unless otherwise explained, the directions in the X axis and Y axis are parallel to a surface 20S serving as a cooling surface of the cooler 20, respectively, and the direction in the Z axis is perpendicular to the surface 20S serving as the cooling surface of the cooler 20. The direction in the Y axis is the direction in which the semiconductor package 11, the semiconductor package 12, and the semiconductor package 13 line up.

The semiconductor device 1 includes the semiconductor package 11, the semiconductor package 12, and the semiconductor package 13 for converting the DC power into the AC power. Note that when it is not necessary to distinguish the semiconductor package 11, the semiconductor package 12, and the semiconductor package 13, the semiconductor package 11, the semiconductor package 12, and the semiconductor package 13 may be collectively referred to as a semiconductor package 10. The semiconductor device 1 further includes the cooler 20 for cooling the semiconductor package 11, the semiconductor package 12, and the semiconductor package 13.

The semiconductor device 1 further includes a seal member 30 which is provided such that it is sandwiched between the respective semiconductor packages 11, 12, 13, and the cooler 20. The seal member 30 has an opening 30h1, an opening 30h2, and an opening 30h3. When the seal member 30 is sandwiched between the semiconductor package 11 and the cooler 20, a closed space (i.e., a space which is closed) SP1 is formed in the opening 30h1. Similarly, when seal 30 the member is sandwiched between the semiconductor package 12 and the cooler 20, a closed space SP2 is formed in the opening 30h2. When the seal member 30 is sandwiched between the semiconductor package 13 and the cooler 20, a closed space SP3 is formed in the opening 30h3.

Further, the semiconductor device 1 includes the thermally conductive member 41 in the closed space SP1. Similarly, the semiconductor device 1 includes the thermally conductive member 42 in the closed space SP2, and includes the thermally conductive member 43 in the closed space SP3.

The semiconductor device 1 also includes a fixing member 50 for fixing the semiconductor packages 11, 12, and 13 and the cooler 20.

### [Semiconductor Package 10]

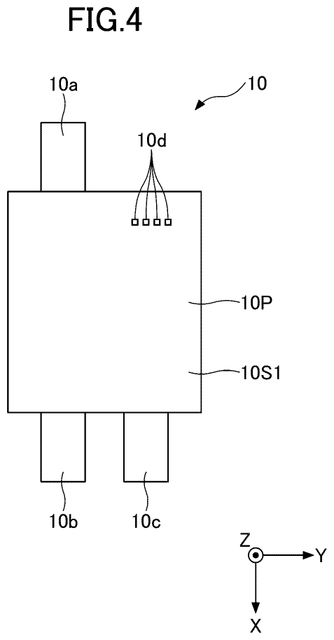

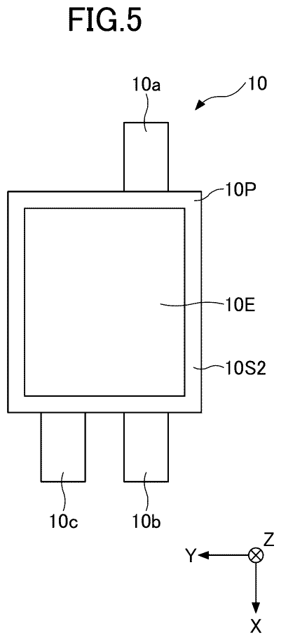

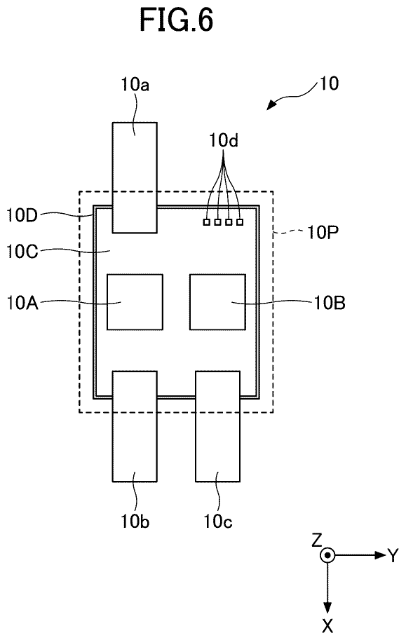

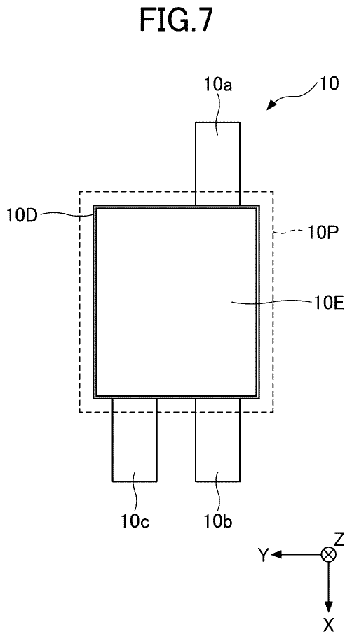

The semiconductor package 11, semiconductor package 12, and semiconductor package 13 will be described with reference to the semiconductor package 10. FIG. 4 is a top view of the semiconductor package 10 provided in the semiconductor device 1 according to the first embodiment. FIG. 5 is a bottom view of the semiconductor package 10 provided in the semiconductor device 1 according to the first embodiment. FIG. 6 is a top view for showing the internal configuration of the semiconductor package 10 provided in the semiconductor device 1 according to the first embodiment. FIG. 7 is a bottom view for showing the internal configuration of the semiconductor package 10 provided in the semiconductor device 1 according to the first embodiment. In FIGS. 6 and 7, a case 10P is shown by a dotted line.

The semiconductor package 10 is, for example, a so-called 2-in-1 semiconductor package in which two semiconductor elements, which constitute upper and lower arms of a one phase component, are packaged. The semiconductor package 10 is a so-called single-sided cooling type semiconductor package. A semiconductor element, such as a power transistor, for example, an IGBT (Insulated Gate Bipolar Transistor) or an FET (Field-Effect Transistor) is incorporated in the semiconductor package 10.

Note that the incorporated semiconductor element may be a power MOSFET (Metal Oxide Semiconductor Field Effect Transistor) or an FWD (Free Wheeling Diode), or the like. Also, the mounted semiconductor element may be an RB-IGBT (Reverse Blocking-Insulated Gate Bipolar Transistor) which is a one-chip version of the above-mentioned IGBT or FWD. Further, the mounted semiconductor element may be an RC-IGBT (Reverse Conducting-Insulated Gate Bipolar Transistor) which is a one-chip version of the above-mentioned IGBT or FWD.

The semiconductor package 10 includes a case 10P of a resin having a substantially rectangular parallelepiped shape, for example, an epoxy resin.

The semiconductor package 10 includes a current terminal 10a, a current terminal 10b, and a current terminal 10c on the side surface of the case 10P. The current terminal 10a, current terminal 10b, and current terminal 10c are provided protruding from the side surface of the case 10P of the semiconductor package 10. The semiconductor package 10 has four control terminals 10d on the upper surface 10S1 of the case 10P. The four control terminals 10d are provided protruding from the upper surface 10S1 of the case 10P of the semiconductor package 10, respectively.

Each of the current terminals 10a, 10b, and 10c is, for example, a terminal for passing a current to a load. Each of the current terminals 10a, 10b, and 10c is formed of a conductive material. Each of the four control terminals 10d is a terminal for controlling a current flowing through the load. Each of the four control terminals 10d is formed of a conductive material.

The semiconductor package 10 has a heat dissipating plate 10E. The heat dissipating plate 10E is formed of, for example, a copper foil. For example, the power transistor incorporated in the semiconductor package 10 is a heat generating element, and thus needs to be cooled. The heat dissipating plate 10E is provided to dissipate the heat generated by the heat generating element. The heat dissipating plate 10E is formed of material having a high thermal conductivity, for example, a metal such as copper. The heat dissipating plate 10E is thermally connected to the heat generating element. The heat dissipating plate 10E is provided on a lower surface 10S2 of the case 10P.

The semiconductor package 10 includes a semiconductor element 10A and a semiconductor element 10B inside the case 10P. The semiconductor package 10 includes a wiring substrate 10C and an insulating substrate 10D inside the case 10P. The semiconductor elements 10A and 10B are mounted on the wiring substrate 10C, respectively. The wiring substrate 10C is formed of, for example, a copper foil. Wirings (not shown) for connecting the semiconductor element 10A or 10B, the current terminals 10a, 10b and 10c, and the respective four control terminals 10d are formed on the wiring substrate 10C. The insulating substrate 10D is formed of, for example, a ceramic. A heat dissipating plate 10E is provided on the-Z side of the insulating substrate 10D.

Each of the semiconductor elements 10A and 10B generates heat. Heat generated from each of the semiconductor elements 10A and 10B is dissipated from the heat dissipating plate 10E.

### [Cooler 20]

The cooler 20 cools the semiconductor package 10. Refrigerant flows inside the cooler 20. The cooler 20 cools the semiconductor package 10 by exchanging heat between the refrigerant (e.g., cooling water) flowing inside the cooler 20, and the semiconductor package 10. Note that the refrigerant is not limited to water, and may be a liquid containing an antifreeze.

The cooler 20 has a refrigerant port 20a and a refrigerant port 20b. Cooled refrigerant is supplied from an external refrigerant supply source via one of the refrigerant ports 20a and 20b. The supplied refrigerant passes through the inside of the cooler 20. When the refrigerant passes through the cooler 20, it exchanges heat with the semiconductor package 10. The refrigerant that passes through the cooler 20 is heated. The refrigerant that is heated and has an increase in temperature is discharged from the other one of the refrigerant ports 20a and 20b.

The cooler 20 has a surface 20S on the +Z side for performing the heat exchange with an object to be cooled. The cooler 20 performs the heat exchange with the object to be cooled via surface the 20S. The semiconductor device 1 includes the semiconductor package 10 via a thermally conductive member on the surface 20S of the cooler 20. The semiconductor package 10 is cooled by the cooler 20. A seal member 30 contacts the surface 20S of the cooler 20. That is, the surface 20S is a surface in contact with the seal member 30.

The cooler 20 is formed of, for example, copper, copper alloy, aluminum, or aluminum alloy. If the thermally conductive members 41, 42, and 43 contain gallium, respectively, the cooler 20 formed of aluminum or aluminum alloy may be corroded by the thermally conductive members. To prevent the corrosion of the cooler 20 by the thermally conductive members, a layer (coating) of copper, copper alloy, nickel, or nickel alloy may be formed at least on the surface 20S. In other words, the cooler 20 may have a layer (coating) formed of copper, copper alloy, nickel, or nickel alloy at its surface. Also, to prevent the corrosion of the cooler 20 by the thermally conductive members, a layer of aluminum oxide may be formed at least on the surface 20S. In other words, the cooler 20 may have a layer of aluminum oxide at its surface.

Note that in this embodiment, although a cooler through which the refrigerant flows is included as the cooler 20, the cooler 20 may be any device so long as it can cool the semiconductor package 10. For example, the cooler 20 may be a heat sink with a plurality of fins for heat dissipation.

### [Seal Member 30]

The seal member 30 holds the thermally conductive members between the semiconductor package 10 and the cooler 20. The seal member 30 is sandwiched between the semiconductor package 10 and the cooler 20. The seal member 30 is provided in close contact with each of the semiconductor package 10 and cooler 20.

The seal member 30 has a predetermined thickness in the Z-axis direction and has a plate-like outer shape extending in the X-axis direction and Y-axis direction. The seal member 30 has an opening 30h1, an opening 30h2, and an opening 30h3 penetrating in the Z-axis direction. That is, the seal member 30 has the opening 30h1, opening 30h2, and opening 30h3 penetrating therethrough between the semiconductor packages 11, 12, and 13, and the cooler 20, when assembled. The seal member 30 is formed of, for example, silicone rubber. The opening 30h1, opening 30h2, and opening 30h3 are shaped like the heat dissipating plates 10E of the semiconductor package 11, semiconductor package 12, and semiconductor package 13, respectively, in a plane view when viewed from the-Z side in the Z-axis direction.

The seal member 30 is placed on the surface 20S of the cooler 20, and the semiconductor package 11, semiconductor package 12, and semiconductor package 13 are placed on the seal member 30. By stacking the cooler 20, the seal member 30, and the semiconductor packages 11, 12, and 13, closed spaces are formed in the opening 30h1, opening 30h2, and opening 30h3 of the seal member 30, respectively.

Specifically, the closed space SP1, which is defined by the semiconductor package 11, the cooler 20, and the seal member 30, is formed between the semiconductor package 11 and the cooler 20 in the opening 30h1 of the seal member 30. Similarly, the closed space SP2, which is defined by the semiconductor package 12, the cooler 20, and the seal member 30, is formed between the semiconductor package 12 and the cooler 20 in the opening 30h2 of the seal member 30. Similarly, the closed space SP3, which is defined by the semiconductor package 13, the cooler 20, and the seal member 30, is formed between the semiconductor package 13 and the cooler 20 in the opening 30h3 of the seal member 30.

The semiconductor device 1 includes the thermally conductive member 41, the thermally conductive member 42, and the thermally conductive member 43 in the opening 30h1, the opening 30h2, and the opening 30h3, respectively. In other words, the semiconductor device 1 includes the thermally conductive member 41, the thermally conductive member 42, and the thermally conductive member 43 in the closed space SP1, the closed space SP2, and the closed space SP3, respectively. The thermally conductive member 41, the thermally conductive member 42, and the thermally conductive member 43 fill in the opening 30h1, the opening 30h2, and the opening 30 h 3, respectively. The thermally conductive member 41, the thermally conductive member 42, and the thermally conductive member 43 fill in the closed space SP1, the closed space SP2, and the closed space SP3, respectively, in a manner that air bubbles or the like are not formed therein.

Note that a shape of the seal member 30 is not limited to that shown in the drawings, and for example, the cross section along the z-axis direction may be in a shape of a trapezoid, circle, ellipse, or rectangle with rounded corners, rather than in a shape of rectangle.

### [Thermally Conductive Members 41, 42, and 43]

Each of the thermally conductive member 41, thermally conductive member 42, and thermally conductive member 43 conducts heat of the semiconductor package 10 to the cooler 20. Each of the thermally conductive member 41, thermally conductive member 42, and thermally conductive member 43 is composed of, for example, a metal that has gallium as a main component and has a fluidity in use.

The semiconductor device 1 has the thermally conductive member 41, thermally conductive member 42, and thermally conductive member 43 in the closed space SP1, closed space SP2, and closed space SP3, respectively. The thermally conductive member 41, thermally conductive member 42, and thermally conductive member 43 fill in the closed space SP1, closed space SP2, and closed space SP3, respectively. The thermally conductive member 41, thermally conductive member 42, and thermally conductive member 43 filling therein transfer heat from the semiconductor package 11, semiconductor package 12 and semiconductor package 13, respectively, to the cooler 20.

In the semiconductor device 1, the thermally conductive member 41 can be brought into close contact each of the with semiconductor package 11 and the cooler 20 by filling the closed space SP1 with the thermally conductive member 41. The heat transfer from the semiconductor package 11 to the cooler 20 can be promoted by bringing the thermally conductive member 41 into close contact with each of the semiconductor package 11 and the cooler 20 by the opening 30h1. Particularly, the heat transfer from the heat dissipating plate 10E to the cooler 20 in the semiconductor package 11 can be promoted, since the opening 30h1 is shaped like the heat dissipating plate 10E of the semiconductor package 11 in a plane view when viewed from the-Z side in the Z-axis direction. Similarly, the heat transfer from the semiconductor package 12 to the cooler 20 can be promoted by bringing the thermally conductive member 42 into close contact with each of the semiconductor package 12 and the cooler 20. The same applies to the thermally conductive member 43.

### [Fixing Member 50]

The fixing member 50 fixes the semiconductor package 11, the semiconductor package 12, and the semiconductor package 13 by pushing them toward the cooler 20. When the fixing member 50 pushes the semiconductor package 11, the semiconductor package 12, and the semiconductor package 13 toward the cooler 20, the seal member 30 is compressed. When the seal member 30 is compressed, airtightness can be ensured in the closed space SP1, the closed space SP2, and the closed space SP3.

The fixing member 50 includes presser plates 51 and 52, bolts 53a and 53b, and nuts 54a and 54b.

The presser plate 51 is provided on the side opposite to the surface 20S of the cooler 20 (−Z side in the Z-axis direction). The presser plate 52 is provided on the side opposite to the cooler 20 (+Z side in the Z-axis direction) of the semiconductor package 11, the semiconductor package 12, and the semiconductor package 13.

Each of the bolts 53a and 53b penetrates through the through holes in the presser plate 51 and presser plate 52. Then, the nuts 54a and 54b are attached to the bolts 53a and 53b, respectively. By tightening each of the nuts 54a and 54b, the presser plates 51 and 52 tighten the semiconductor packages 11, 12, and 13, and the cooler 20. When the presser plate 51 and presser plate 52 tighten the semiconductor packages 11, 12, and 13, and the cooler 20, the semiconductor packages 11, 12 and 13 are pushed toward the cooler 20.

The semiconductor device 1 is assembled by pushing the semiconductor package 11, semiconductor package 12, and semiconductor package 13 toward the cooler 20 by the fixing member 50. The fixing member 50 presses the semiconductor package 11, semiconductor package 12, and semiconductor package 13 against the cooler 20. Note that a configuration of the fixing member 50 is not limited to the above, and a fastening method by bolts and nuts may be suitably changed. Also, a shape of the presser plate is not limited to the above, and may be suitably changed.

### <Assembly of Semiconductor Device 1>

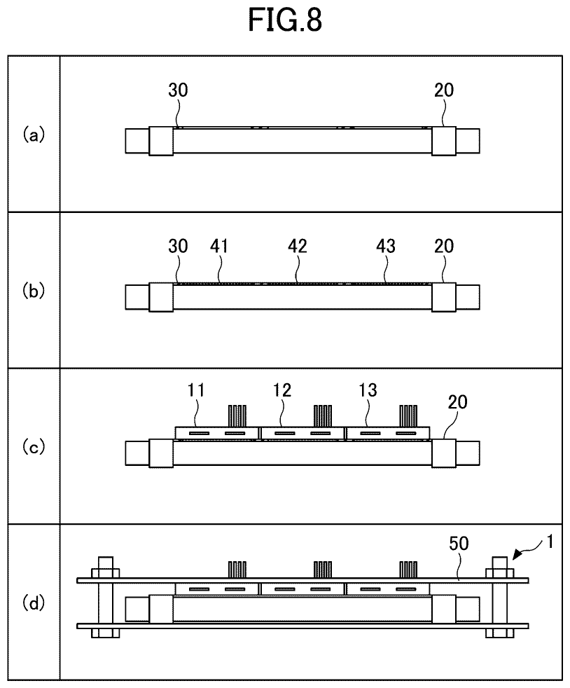

The assembly of the semiconductor device 1 will be described in more detail. FIG. 8 is a view for explaining the assembly of the semiconductor device 1 according to the first embodiment.

Initially, the seal member 30 is placed on the cooler 20, more specifically, on the surface 20S of the cooler 20 (the part (a) of FIG. 8). Note that in the parts (a), (b), and (c) of FIG. 8, the seal member 30 is shown in a cross-sectional view.

Next, the thermally conductive member 41, the thermally conductive member 42, and the thermally conductive member 43 fill in the opening 30h1, the opening 30h2, and the opening 30h3 of the seal member 30, respectively (the part (b) of FIG. 8). Then, the semiconductor package 11, the semiconductor package 12, and the semiconductor package 13 are placed on the seal member 30 (the part (c) of FIG. 8).

Then, the semiconductor packages 11, 12, and 13, and the cooler 20 are fixed by the fixing member 50 (the part (d) of FIG. 8). The semiconductor packages 11, 12, and 13, and the cooler 20 are fixed by the fixing member 50, and the assembly of the semiconductor device 1 is completed.

In accordance with the semiconductor device 1 according to the first embodiment, the semiconductor 11, the package semiconductor package 12, and the semiconductor package 13 can be stably cooled by providing the thermally conductive member 41, the thermally conductive member 42, and the thermally conductive member 43 having a fluidity. Since the thermally conductive member 41, the thermally conductive member 42, and the thermally conductive member 43 have a fluidity, and in other words, are not in a solid state, the thermally conductive member 41, the thermally conductive member 42, and the thermally conductive member 43 do not peel or crack during operation. In addition, since the semiconductor device 1 includes the thermally conductive member 41, the thermally conductive member 42, and the thermally conductive member 43 in the closed space SP1, the closed space SP2, and the closed space SP3, respectively, the thermally conductive member 41, the thermally conductive member 42, and the thermally conductive member 43 can be prevented from spreading outward from the closed space. Therefore, in accordance with the semiconductor device 1, the semiconductor package 11, the semiconductor package 12, and the semiconductor package 13 can be stably cooled. In accordance with the semiconductor device 1, a semiconductor device having a high reliability can be provided.

For example, when a solder or metal powder sintered body is used for the connection between a semiconductor package and a cooler, it is necessary to raise the temperature when joining them using the solder or metal powder sintered body. When the temperature of the semiconductor package and the cooler is raised, the semiconductor package and the cooler may be damaged by thermal stress. In addition, when the metal powder sintered body is used, it is necessary to pressurize it to obtain a sufficient bonding strength. When the semiconductor package and the cooler are pressurized, the semiconductor package and the cooler may be damaged by the pressurization.

In accordance with the semiconductor device 1 according to the first embodiment, the semiconductor packages 11, 12, and 13, and the cooler 20 can be connected by the thermally conductive member 41, thermally conductive member 42, and thermally conductive member 43 having a fluidity without raising the temperature or pressurizing. Therefore, according to the semiconductor device 1, damage to the semiconductor package 11, the semiconductor package 12, the semiconductor package 13, and the cooler 20 can be prevented during assembly.

For example, when a solder or metal powder sintered body is used for the connection between the semiconductor package and the cooler, there is a possibility that the solid solder or metal powder sintered body is damaged by a thermal stress during operation of the semiconductor device. For example, when the solder or metal powder sintered body is used for the connection between the semiconductor package and the cooler, there is a possibility that the solid solder or metal powder sintered body is damaged by a vibration during vehicle operation when used in an electric vehicle. If the solid solder or metal powder sintered body is damaged, a heat transfer function and a bonding function may be impaired. Especially in semiconductor devices for electric vehicles, it is required that the heat transfer function and the fixing function are maintained even when a vibration occurs.

In accordance with the semiconductor device 1 according to the first embodiment, by using the thermally conductive member 41, the thermally conductive member 42, and the thermally conductive member 43 having a fluidity, it is possible to prevent the damage caused by the vibration or the like and the deterioration of the functions.

### Second Embodiment

Next, a semiconductor device according to the second embodiment will be described. The semiconductor device according to the second embodiment differs from the semiconductor device 1 according to the first embodiment in fixing the means of the semiconductor package. The semiconductor device according to the second embodiment fixes the semiconductor package with an adhesive.

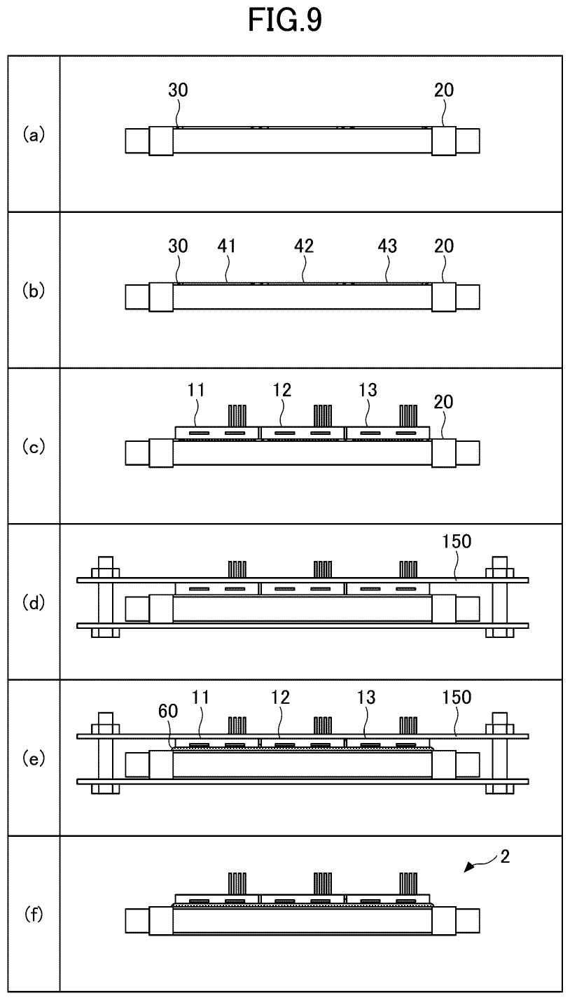

FIG. 9 is a view for explaining the assembly of the semiconductor device 2 according to the second embodiment. The parts (a), (b) and (c) of FIG. 9 have the same contents as the parts (a), (b) and (c) of FIG. 8, respectively, and thus the description thereof is omitted. The processing from the part (d) of FIG. 9 will be described below.

After placing the semiconductor package 11, the semiconductor package 12, and the semiconductor package 13 on the seal member 30, the semiconductor packages 11, 12, and 13, and the cooler 20 are fixed by the fixing jig 150 (the part (d) of FIG. 9).

Then, an adhesive 60 is applied to the junctions between the semiconductor packages 11, 12, and 13, and the seal member 30 (the part (e) of FIG. 9). The adhesive 60 is also applied between the semiconductor package 11 and the semiconductor package 12, and between the semiconductor package 12 and the semiconductor package 13. Then, the adhesive 60 is left for a certain period until it cures.

Then, after the adhesive 60 is cured, the fixing jig 150 is removed (the part (f) of FIG. 9). The assembly of the semiconductor device 2 is completed.

In accordance with the semiconductor device 2 according to the second embodiment, the semiconductor package 11, the semiconductor package 12, and the semiconductor package 13 can be stably cooled in the same manner as the semiconductor device 1 according to the first embodiment. In addition, in accordance with the semiconductor device 2 according to the second embodiment, the miniaturization can be achieved.

### Third Embodiment

Next, a semiconductor device according to the third embodiment will be described. The semiconductor device according to the third embodiment differs from the semiconductor device 1 according to the first embodiment in the fixing means of the semiconductor package. The semiconductor device according to the third embodiment fixes the semiconductor package with a sealing resin.

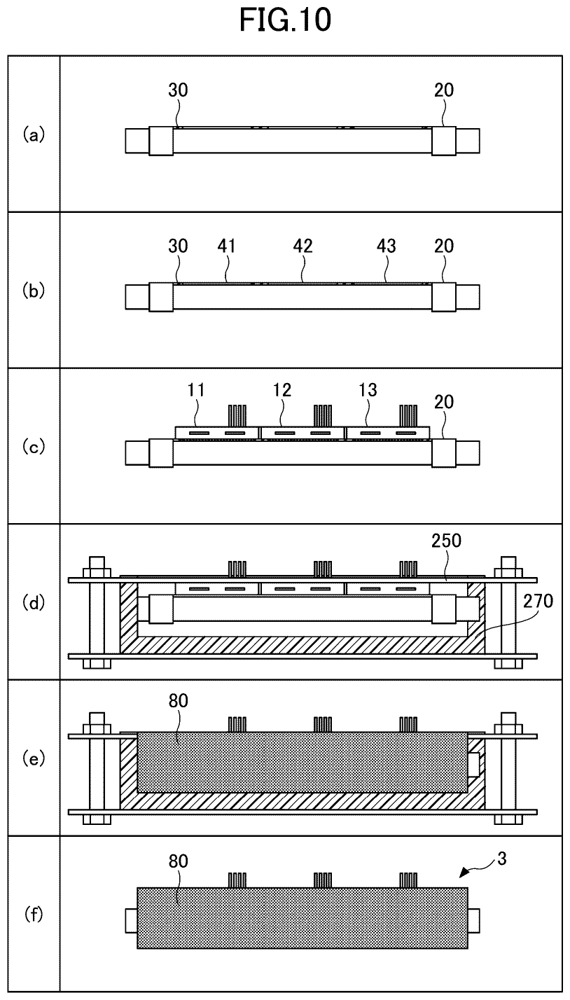

FIG. 10 is a view for explaining the assembly of the semiconductor device 3 according to the third embodiment. The parts (a), (b), and (c) of FIG. 10 have the same contents as the parts (a), (b), and (c) of FIG. 8, respectively, and thus the description thereof is omitted. The processing from the part (d) of FIG. 10 will be described below. In the parts (d) and (e) of FIGS. 10, a mold 270 is shown in a cross-sectional view.

After being placed on the seal member 30, the semiconductor package 11, the semiconductor package 12, and the semiconductor package 13 are placed in the mold 270, and fixed by the fixing jig 250 (the part (d) of FIG. 10).

Then, the mold 270 is filled with the sealing resin 80 therein (the part (e) of FIG. 10). Then, the sealing resin 80 is left for a certain period until the sealing resin is cured. Then, after the sealing resin 80 is cured, the fixing jig 250 is removed (the part (f) of FIG. 10). Then, the assembly of the semiconductor device 3 is completed.

The assembled semiconductor device 3 includes the sealing resin 80. The sealing resin 80 seals the semiconductor packages 11, 12, and 13, the cooler 20, and the seal member 30.

In accordance with the semiconductor device 3 according to the third embodiment, the semiconductor package 11, the semiconductor package 12, and the semiconductor package 13 can be stably cooled in the same manner as the semiconductor device 1 according to the first embodiment. Further, in accordance with the semiconductor device 3 according to the third embodiment, by providing the sealing resin 80, an influence from the external environment can be suppressed, and thus the environmental resistance can be improved.

### Fourth Embodiment

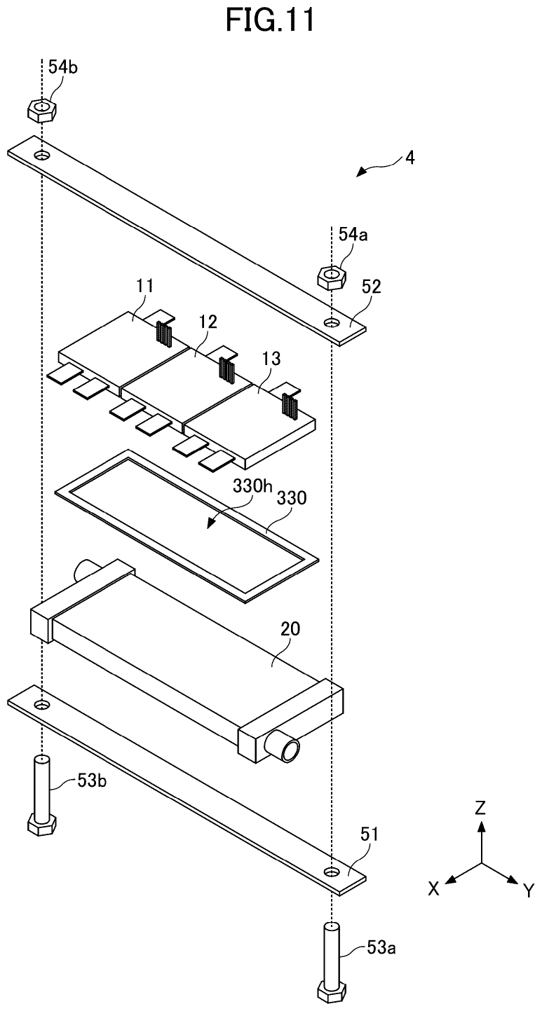

Next, a semiconductor device according to the fourth embodiment will be described. FIG. 11 is an exploded perspective view of the semiconductor device 4 according to the fourth embodiment. In FIG. 11, the thermally conductive members are not shown. The semiconductor device 4 according to the fourth embodiment includes a seal member 330 instead of the seal member 30 in the semiconductor device 1 according to the first embodiment.

The seal member 330 holds a thermally conductive member between the semiconductor package 10 and the cooler 20. The seal member 330 is sandwiched between the semiconductor package 10 and the cooler 20. The seal member 330 is provided in close contact with each of the semiconductor package 10 and the cooler 20.

The seal member 330 has a predetermined thickness in the Z-axis direction, and has a plate-like outer shape extending in the X-axis direction and Y-axis direction. The seal member 330 has an opening 330h that penetrates in the Z-axis direction. That is, when assembled, the seal member 330 has an opening 330h that penetrates therethrough between the semiconductor packages 11, 12, and 13 and the cooler 20. The seal member 30 is formed of, for example, silicone rubber.

The seal member 330 is placed on the surface 20S of the cooler 20, and the semiconductor package 11, the semiconductor package 12, and the semiconductor package 13 are placed on the seal member 330. By stacking the cooler 20, the seal member 330, and the semiconductor packages 11, 12, and 13, a closed space is formed in the opening 330h of the seal member 330.

The semiconductor device 4 includes a thermally conductive member in the opening 330h. The thermally conductive member fills in the opening 330h.

In accordance with the semiconductor device 4 according to the fourth embodiment, the semiconductor package 11, the semiconductor package 12, and the semiconductor package 13 can be stably cooled in the same manner as the semiconductor device 1 according to the first embodiment.

### Fifth Embodiment

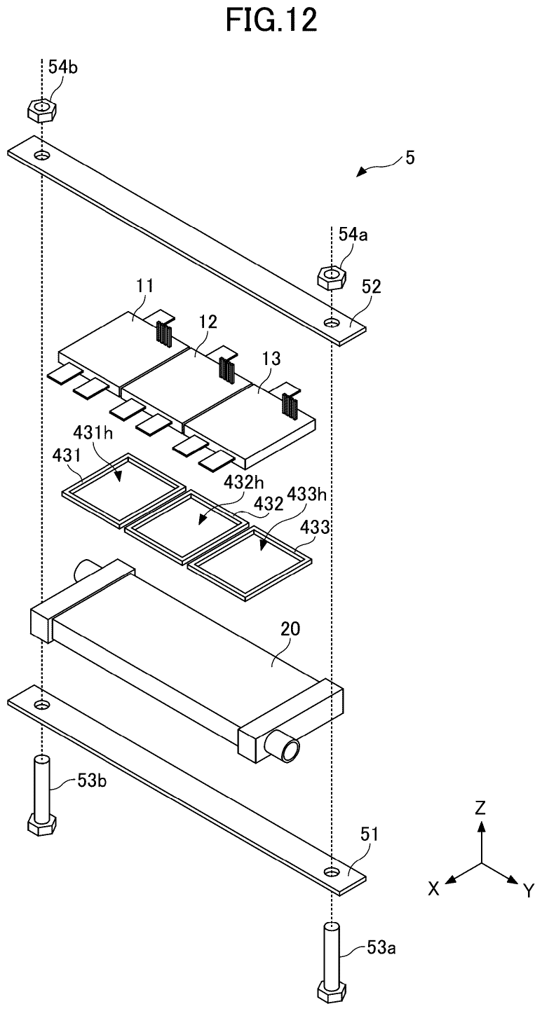

Next, a semiconductor device according to the fifth embodiment will be described. FIG. 12 is an exploded perspective view of the semiconductor device 5 according to the fifth embodiment. Note that in FIG. 12, the thermally conductive members are not shown. The semiconductor device 5 according to the fifth embodiment includes a seal member 431, a seal member 432, and a seal member 433, instead of the member 30 in the seal semiconductor device 1 according to the first embodiment.

The seal member 431, seal member 432, and seal member 433 hold a thermally conductive member between the semiconductor package 10 and the cooler 20. The seal member 431, seal member 432, and seal member 433 are sandwiched between the semiconductor package 10 and the cooler 20. The seal member 431, seal member 432, and seal member 433 are provided in close contact with each of the semiconductor package 10 and the cooler 20.

The seal member 431, seal member 432 and seal member 433 are members having a predetermined thickness in the Z-axis direction and having a plate-like outer shape extending in the X-axis direction and Y-axis direction. Further, the seal member 431, seal member 432, and seal member 433 have an opening 431h, an opening 432h, and an opening 433h penetrating in the Z-axis direction, respectively. That is, when assembled, the seal member 431 has an opening 431h penetrating therethrough between the semiconductor package 11 and the cooler 20. When assembled, the seal member 432 has an opening 432h penetrating therethrough between the semiconductor package 12 and the cooler 20. When assembled, the seal member 433 has an opening 433h penetrating therethrough between the semiconductor package 13 and the cooler 20. The seal member 431, seal member 432, and seal member 433 are formed of, for example, silicone rubber.

The seal members 431, 432, and 433 are placed on the surface 20S of the cooler 20, and the semiconductor packages 11, 12, and 13 are, respectively, placed on the seal members 431, 432, and 433. By stacking the cooler 20, the seal member 431, and the semiconductor package 11, a closed space is formed in the opening 431h of the seal member 431. Similarly, by stacking the cooler 20, the seal members 432, 433, and the semiconductor packages 12, 13, closed spaces are formed in the respective openings 432h and 433h.

The semiconductor device 5 includes thermally conductive members in the opening 431h, the opening 432h, and the opening 433h. The thermally conductive members fill in the opening 431h, the opening 432h, and the opening 433h, respectively.

In accordance with the semiconductor device 5 according to the fifth embodiment, the semiconductor package 11, the semiconductor package 12, and the semiconductor package 13 can be stably cooled in the same manner as the semiconductor device 1 according to the first embodiment.

### Sixth Embodiment

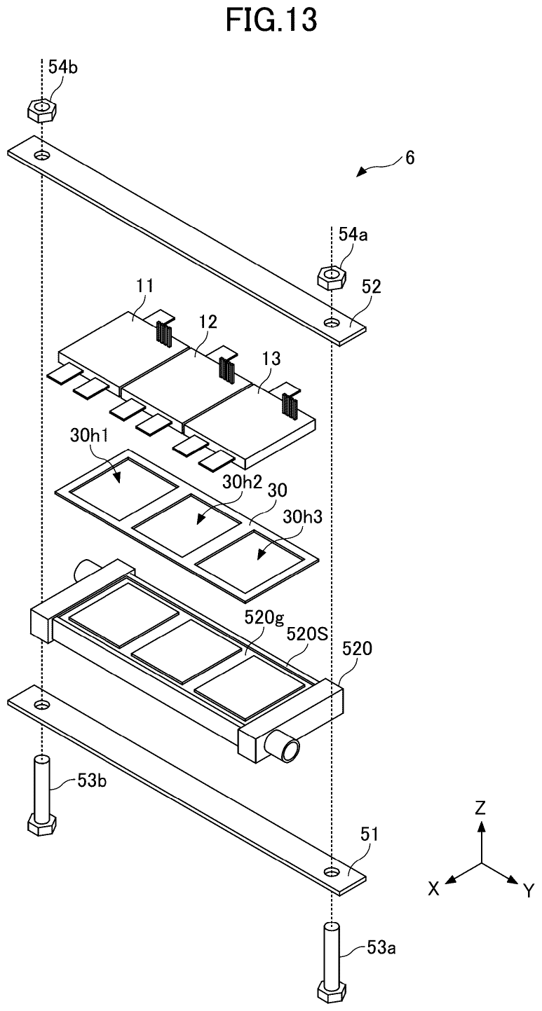

Next, a semiconductor device according to the sixth embodiment will be described. FIG. 13 is an exploded perspective view of the semiconductor device 6 according to the sixth embodiment. Note that in FIG. 13, the thermally conductive members are not shown. The semiconductor device 6 according to the sixth embodiment includes a cooler 520 instead of the cooler 20 in the semiconductor device 1 according to the first embodiment.

The cooler 520 has a groove 520g on a surface 520S on the +Z side, which is shaped like the seal member 30 in a plane view when viewed from the +Z side in the Z-axis direction. When the seal member 30 is placed on the cooler 520, the seal member 30 is inserted into the groove 520g. When the seal member 30 is placed on the cooler 520, the seal member 30 can be positioned relative to the cooler 520 by inserting the seal member 30 into the groove 520g.

In accordance with the semiconductor device 6 according to the sixth embodiment, the semiconductor package 11, the semiconductor package 12, and the semiconductor package 13 can be stably cooled in the same manner as the semiconductor device 1 according to the first embodiment. In addition, in accordance with the semiconductor device 6 according to the sixth embodiment, an assembly work of the semiconductor device 6 can be facilitated.

Note that the groove 520g is an example of the first groove.

### Seventh Embodiment

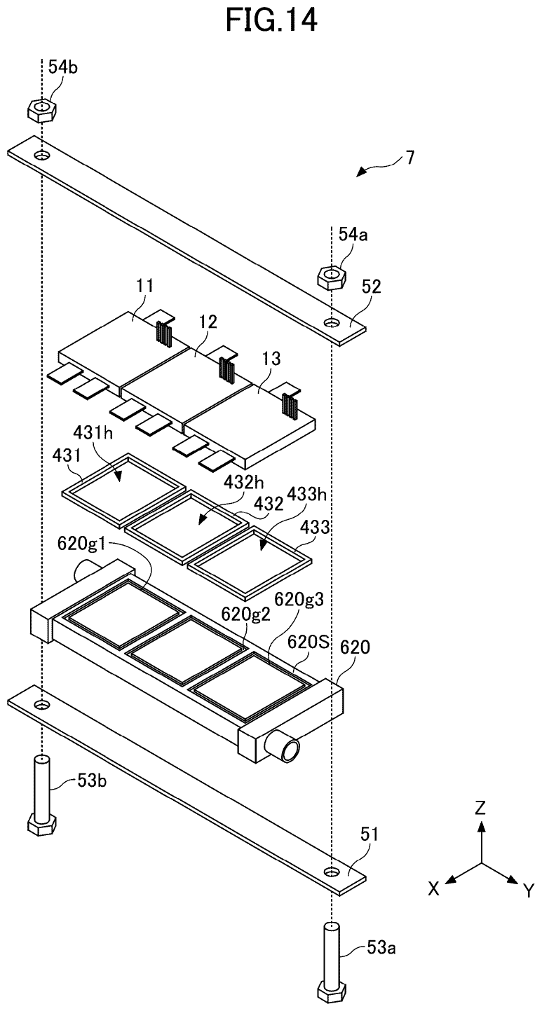

Next, a semiconductor device according to the seventh embodiment will be described. FIG. 14 is an exploded perspective view of the semiconductor device 7 according to the seventh embodiment. In FIG. 14, the thermally conductive members are not shown. The semiconductor device 7 according to the seventh embodiment includes a cooler 620 instead of the cooler 20 in the semiconductor device 4 according to the fourth embodiment.

The cooler 620 has a groove 620g1, a groove 620g2, and a groove 620g3 on the surface 620S on the +Z side, which are shaped like the seal member 431, seal member 432, and seal member 433, respectively, in a plane view when viewed from the +Z side in the Z axis direction. When placing the seal member 431 on the cooler 620, the seal member 431 is inserted into the groove 620g1. By inserting the seal member 431 into the groove 620g1, the seal member 431 can be positioned relative to the cooler 620 when placing the seal member 431 on the cooler 620. Similarly, when placing the seal member 432 and the seal member 433 on the cooler 620, the seal member 432 and the seal member 433 are inserted into the groove 620g2 and the groove 620g3, respectively.

In accordance with the semiconductor device 7 according to the seventh embodiment, the semiconductor package 11, the semiconductor package 12, and the semiconductor package 13 can be stably cooled in the same manner as the semiconductor device 1 according to the first embodiment. In accordance with the semiconductor device 7 according to the seventh embodiment, an assembly work of the semiconductor device 7 can be facilitated.

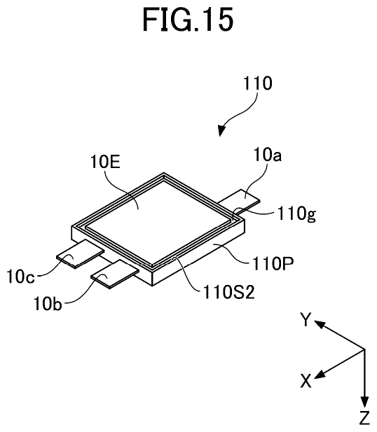

The semiconductor package 10 may also include a groove for inserting the seal member therein. FIG. 15 is a perspective view of the semiconductor package 110, which is a modified example of the semiconductor package provided in the semiconductor device 7 according to the seventh embodiment. In the semiconductor device 7, the semiconductor package 110 may be used instead of the semiconductor package 11, the semiconductor package 12, and the semiconductor package 13.

The semiconductor package 110 has, in a case 110P, grooves 110g on the lower surface 110S2 which are shaped like the seal member 431, seal member 432, and seal member 433, respectively, in a plane view viewed from the +Z side in the Z axis direction. When placing the semiconductor package 110 on each of the seal member 431, seal member 432, and seal member 433, the semiconductor package 110 can be positioned on each of the seal member 431, seal member 432, and seal member 433.

Note that the semiconductor package 110 may be applied to any of the semiconductor packages 11, 12, and 13 of the semiconductor device 4 according to the fourth embodiment.

Each of the grooves 620g1, 620g2, and 620g3 is an example of the first groove, and the groove 110g is an example of the second groove.

It should be noted that the embodiments disclosed herein are illustrative in all respects and should not be considered exhaustive or restrictive. The embodiments described above may be omitted, replaced, or modified in various forms without departing from the scope and spirit of the appended claims.

What is claimed is:

1. A semiconductor device, comprising:
a semiconductor package;
a cooler configured to cool the semiconductor package;
a seal member provided between the semiconductor package and the cooler, the seal member having an opening penetrating therethrough between the semiconductor package and the cooler; and
a thermally conductive member formed of a metal filling the opening, the metal having a fluidity.

2. The semiconductor device as claimed in claim 1, wherein the cooler has, on a surface thereof in contact with the seal member, a first groove into which the seal member is inserted.

3. The semiconductor device as claimed in claim 1, wherein the semiconductor package has, on a surface thereof in contact with the seal member, a second groove into which the seal member is inserted.

4. The semiconductor device as claimed in claim 1, wherein the cooler has, on a surface thereof in contact with the seal member, a first groove into which the seal member is inserted, and the semiconductor package has, on a surface thereof in contact with the seal member, a second groove into which the seal member is inserted.

5. The semiconductor device as claimed in claim 1, wherein the cooler formed of copper or copper alloy.

6. The semiconductor device as claimed in claim 1, wherein the cooler is formed of aluminum or aluminum alloy.

7. The semiconductor device as claimed in claim 6, wherein the cooler has a layer formed of copper, copper alloy, nickel, or nickel alloy at a surface thereof.

8. The semiconductor device as claimed in claim 6, wherein the cooler has a layer of aluminum oxide at a surface thereof.

9. The semiconductor device as claimed in claim 1, further comprising:
a fixing member configured to press the semiconductor package against the cooler.

10. The semiconductor device as claimed in claim 1, further comprising:
an adhesive configured to fix the semiconductor package and the seal member.

11. The semiconductor device as claimed in claim 1, further comprising:
a sealing resin configured to seal the semiconductor package, the seal member, and the cooler.

12. A power converter comprising the semiconductor device of claim 1, wherein the semiconductor package is configured to convert direct current power into alternating current power.
